(19) United States
(12) Patent Application Publication
(10) Pub. No.: US 2011/0182761 A1
(43) Pub. Date: Jul. 28, 2011

(54) STATOR FOR USE IN HELICOIDAL MOTOR

(75) Inventor: Geoffrey Frederick Archer, Lincolnshire (GB)

(73) Assignee: Advanced Interactive Materials Science Limited, Westwood, Peterborough (GB)

(21) Appl. No.: 12/736,206

(22) PCT Filed: Mar. 20, 2009
(86) PCT No.: PCT/GB2009/000754

§ 371 Date: Dec. 26, 2010

(30) Foreign Application Priority Data
Mar. 20, 2008 (GB) 0805250.8

(51) Int. Cl. F04C 2/107; B22F 3/02; B23P 17/04; B22F 3/24; B05D 3/10; C23C 16/40; F04C 15/00; B22F 7/08

(52) U.S. Cl. 418/48; 419/68; 29/527.1; 427/327; 216/37; 427/255.19; 419/8

(57) ABSTRACT

A stator for a helicoidal down-hole drilling motor is formed with a through-hole, in addition to the main stator bore. The through-hole can be a straight hole extending parallel to the axis of the stator, or a hole of helical form, the helix extending about the axis of the stator. The through-hole can be used to accommodate a communications cable extending through the through-hole, and/or the through-hole can be connected to a fluid supply. The stator is produced from metal-based powder by producing an insert of accurate dimensions corresponding to the dimensions of a bore to be created in the finished stator, the bore having a length of at least 750 mm, supporting the insert within a mould cavity, filling the mould cavity with metal-based powder, subjecting the powder to isostatic pressing, and subsequently removing the material of the insert.

This invention relates to stators for use in helicoidal motors used in down-hole drilling.

Down-hole drilling heads are often driven by a helicoidal motor positioned close to the drilling head and operated by a mud pump. The helicoidal motor comprises a stator coupled to the drill string, and a rotor coupled to the drilling head.

Such helicoidal motors work under very arduous conditions.

We have appreciated that in various circumstances there would be advantage in providing a hole in the stator, for example to accommodate a communications link and/or fluid flow.

It has not previously been possible to create a hole through a metal stator manufactured from the advanced materials that are required to provide a metal stator suitable to resist the abrasive, corrosive and erosive conditions to which a down-hole drilling stator is subjected in use, since such metals cannot be drilled except for creating very short holes.

According to one aspect of the invention we provide a stator for a helicoidal down-hole drilling motor, the stator being formed with a through-hole, in addition to the main stator bore.

The stator is preferably produced by a powder metallurgy process.

The hole may extend in any direction through the stator. In particular the hole may be a straight hole extending parallel to the axis of the stator, or the hole may be of helical form, the helix extending about the axis of the stator.

The invention thus provides a hole through the stator part of the linear motor/pump through which information can be transmitted either way to control and/or collect data and information.

The information can be transmitted via electrically conductive materials and/or optical fibres. More than one hole can be placed through the metal stator at a size that does not undermine the strength of the stator but optimises the potential uses of such a hole.

Potentially, but not essentially, the hole can be used for other things including cooling, and/or fluid transmission in addition to transmission of signals in electrical and optical form. In such an instance the hole may, but not essentially, follow the helical form of the internal shape of a stator provided internally with one or more helical flutes.

Such information transmitted through the hole can be typically but not essentially restricted to the collection of temperature, pressure, flow rate, load torque and vibration. It can also be seen that such a hole could provide the means of controlling aspects of a drilling head in such a way that is currently not available in association with a metal stator.

According to a second aspect of the invention a method of producing a net or near net-shape helicoidal motor stator from metal-based powder comprises producing an insert of accurate dimensions corresponding to the dimensions of a bore to be created in the finished stator, the bore having a length of at least 750 mm, supporting the insert within a mould cavity, filling the mould cavity with metal-based powder, subjecting the powder to isostatic pressing, and subsequently removing the material of the insert.

As is well known, the mould may be an independent mould that is removed after an initial step to bind the powder together into a pre-form, and the pre-form is then encapsulated in a suitable containment which may be a canister or a sprayed coating, or a canister of suitable internal shape may be used as the mould, and the canister itself is evacuated prior to HIPing

Preferably the insert is supported in position in the mould cavity by a plurality of formers of a material that is compatible with the finally consolidated powder.

The insert may be a metallic insert of a material that is subsequently removable by chemical etching, preferably copper. The chemical etching may be assisted by electrolytic reaction.

In suitable cases the insert need only be coated with a material that can subsequently be removed by etching, in order to release the insert, which can then be extracted.

Preferably the metallic insert is coated with a suitable material that provides a diffusion barrier to prevent the material of the insert from diffusing by atomic diffusion into the powder being consolidated during HIPing.

The invention can enable a helical bore to be provided in a stator.

In one preferred embodiment a copper rod, of a diameter in the range of 6 to 10 mm for example and of length greater than 2 m, is first bent into a helix of the required dimensions and this is then held in position in a powder containment prior to filling the containment with powder. The containment enclosing the powder, rod and former, is then consolidated by solid state diffusion using the HIPing method.

The diffusion barrier may be Al₂O₃ applied by vapour phase deposition or by high velocity spraying. Alternatively, the diffusion barrier may be created by applying boron nitride as an aqueous solution by spraying.

In a second embodiment a preformed metal tube, of 6 mm to 10 mm diameter for example, is filled with ceramic particles and is bent to a helical shape and placed within the powder containment prior to filling the containment with powder. The tube is held in position with formers compatible with the finally consolidated powder. The entire containment encompassing the metallic and/or cermet/MMC powder is then consolidated by solid state diffusion using the HIPing method.

During consolidation the metal tube may become totally diffusion bonded into the consolidated component but the ceramic particles will remain in the pre-process particle form and thereby can be removed mechanically via vibration techniques to leave a clean hole through the component.

### EXAMPLE

The invention can be used to provide one or more holes in one or more helical lobes provided internally of a stator body having a length of as much as 2 m or more. The hole or holes can be positioned to follow the core of a helical flute, which may have a pitch of about 1 m and a radius of 50 mm about the body axis. The helical lobes are defined by helical grooves in a mandrel that is positioned in the mould during pressing of the stator body.

1. A stator for a helicoidal down-hole drilling motor, the stator being formed with a through-hole, in addition to the main stator bore.

2. A stator as claimed in claim 1 in which the through-hole is a straight hole extending parallel to the axis of the stator.

3. A stator as claimed in claim 1 in which the through-hole is of helical form, the helix extending about the axis of the stator.

4. A helicoidal down-hole drilling motor comprising a stator as claimed in claim 1 and provided with a communications cable extending through the through-hole.

5. A helicoidal down-hole drilling motor as claimed in claim 4 in which the communications cable is a fibre optics cable.

6. A drilling motor as claimed in claim 4 in which the through-hole is connected to a fluid supply.

7. A drilling motor as claimed in claim 6 in which the through-hole follows the helical form of the internal shape of a stator provided internally with one or more helical flutes.

8. A method of producing a net or near net-shape helicoidal motor stator from metal-based powder comprising producing an insert of accurate dimensions corresponding to the dimensions of a bore to be created in the finished stator, the bore having a length of at least 750 mm, supporting the insert within a mould cavity, filling the mould cavity with metal-based powder, subjecting the powder to isostatic pressing, and subsequently removing the material of the insert.

9. The method of claim 8 in which the mould is an independent mould that is removed after an initial step to bind the powder together into a pre-form, and the pre-form is then encapsulated in a suitable containment.

10. The method of claim 9 in which the containment is a canister.

11. The method of claim 9 in which the containment is a sprayed coating.

12. The method of claim 8 in which the insert is supported in position in the mould cavity by a plurality of formers of a material that is compatible with the finally consolidated powder.

13. The method of claim 8 in which the insert is a metallic insert of a material that is subsequently removable by chemical etching.

14. The method of claim 13 in which the insert comprises copper.

15. The method of claim 14 in which the chemical etching is assisted by electrolytic reaction.

16. The method of claim 8 in which the insert is coated with a material that is amenable to removal by etching, and comprising the steps of releasing the insert by etching the coating, and then extracting the insert.

17. The method of claim 13 in which the metallic insert is coated with a material that provides a diffusion barrier to prevent the material of the insert from diffusing by atomic diffusion into the powder being consolidated during HIPing.

18. The method of claim 17 in which the diffusion barrier comprises Al₂O₃ applied by vapour phase deposition.

19. The method of claim 17 in which the diffusion barrier comprises Al₂O₃ applied by high velocity spraying.

20. The method of claim 17 in which the diffusion barrier is created by applying boron nitride as an aqueous solution by spraying.

21. The method of claim 8 in which the insert is produced by taking a copper rod, of a diameter in the range of 6 to 10 mm and of length greater than 2 m, bending the copper rod into a helix of the required dimensions, and then holding the helical rod in position in a powder containment prior to filling the containment with powder, the containment enclosing the powder, rod and former, and then consolidating the powder by solid state diffusion using a HIPing method.

22. The method of claim 8 in which the insert is produced by taking a preformed metal tube, of 6 mm to 10 mm diameter, filling the tube with ceramic particles, and bending the filled tube to a helical shape, placing the helical filled tube within the powder containment prior to filling the containment with powder, holding the tube in position with formers compatible with the finally consolidated powder, providing a containment encompassing the metallic and/or cermet/MMC powder, and then consolidating the contained material by solid state diffusion using a HIPing method.

23. The method of claim 22 comprising removing the ceramic particles mechanically by a vibration technique to leave a clean hole through the finished component.
